(19) United States
(12) Patent Application Publication
(10) Pub. No.: US 2022/0352337 A1
(43) Pub. Date: Nov. 3, 2022

(54) SEMICONDUCTOR DEVICE AND MANUFACTURING METHOD THEREOF

(71) Applicant: INNOSCIENCE (SUZHOU) SEMICONDUCTOR CO., LTD., SUZHOU CITY (CN)

(72) Inventors: Chang An LI, ZHUHAI CITY (CN); Ming-Hong CHANG, ZHUHAI CITY (CN)

(21) Appl. No.: 17/257,292

(22) PCT Filed: Nov. 27, 2020
(86) PCT No.: PCT/CN2020/132067

§ 371 Date: Dec. 30, 2020

(51) Int. Cl. H01L 29/45; H01L 29/66; H01L 29/40

(52) U.S. Cl. CPC H01L 29/452; H01L 29/66462; H01L 29/401; H01L 29/7786

(57) ABSTRACT

The present disclosure relates to a semiconductor device and a fabrication method thereof. The semiconductor device includes a substrate, a first nitride semiconductor layer disposed on the substrate, a second nitride semiconductor layer disposed on the first nitride semiconductor layer, a passivation layer disposed on the second nitride semiconductor layer, a first adhesive layer disposed on the passivation layer. The semiconductor device further includes a conductive contact disposed on the first adhesive layer and extending through the first adhesive layer into the passivation layer, the conductive contact has a first overhang on the passivation layer and in direct contact with the first adhesive layer, and the conductive contact comprising a first element. A concentration of the first element is less than approximate 3% around to a contact between the first overhang and the passivation layer.

### BACKGROUND

### 1. Technical Field

The present disclosure relates to the semiconductor field, more particularly to a high electron mobility transistor (HEMT) having high carrier concentration and high carrier mobility, and a fabrication method thereof.

### 2. Description of the Related Art

A high electron mobility transistor (HEMT) is a field effect transistor. A HEMT is different from a metal-oxide-semiconductor (MOS) transistor in that the HEMT adopts two types of materials having different bandgaps that form a heterojunction, and the polarization of the heterojunction forms a two-dimensional electron gas (2DEG) region in the channel layer for providing a channel for the carriers. HEMTs have drawn a great amount of attention due to their excellent high frequency characteristics. HEMTs can operate at high frequencies because the current gain of HEMTs can be multiple times better than MOS transistors, and thus can be widely used in various mobile devices.

Research is continuously conducted by adopting different materials in the manufacturing of HEMTs, for the purpose of achieving HEMTs that can have better performance.

### SUMMARY

According to some embodiments of the present disclosure, a semiconductor device is provided. The semiconductor device includes a substrate, a first nitride semiconductor layer disposed on the substrate, a second nitride semiconductor layer disposed on the first nitride semiconductor layer, a passivation layer disposed on the second nitride semiconductor layer, a first adhesive layer disposed on the passivation layer. The semiconductor device further includes a conductive contact disposed on the first adhesive layer and extending through the first adhesive layer into the passivation layer; the conductive contact has a first overhang on the passivation layer and is in direct contact with the first adhesive layer, and the conductive contact comprises a first element. A concentration of the first element is less than approximately 3% around a contact between the first overhang and the passivation layer.

According to some embodiments of the present disclosure, a semiconductor device is provided. The semiconductor device includes a substrate; a first nitride semiconductor layer disposed on the substrate; a second nitride semiconductor layer disposed on the first nitride semiconductor layer and having a bandgap greater than that of the first nitride semiconductor layer. The semiconductor device includes a passivation layer on the first nitride semiconductor layer and a first adhesive layer disposed on the passivation layer. The semiconductor device further includes a conductive contact having a first portion away from the second nitride semiconductor layer and a second portion adjacent the second nitride semiconductor layer. The first portion of the conductive contact comprises a first semiconductor material.

According to some embodiments of the present disclosure, a method for fabricating a semiconductor device is provided. The method comprises providing a semiconductor structure having a substrate, a first nitride semiconductor layer and a passivation layer. The method comprises removing a portion of the passivation layer to form a trench exposing a surface of the first nitride semiconductor layer. The method further comprises applying a conductive layer on the passivation layer to fill the trench, wherein the conductive layer includes a semiconductor material (Si) and a metal material (Al).

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1A illustrates a cross-sectional view of a semiconductor device according to some embodiments of the present disclosure;

FIG. 1B illustrates a cross-sectional view of a semiconductor device according to some embodiments of the present disclosure;

FIG. 1C illustrates a cross-sectional view of a semiconductor device according to some embodiments of the present disclosure;

FIG. 1D illustrates a cross-sectional view of a semiconductor device according to some embodiments of the present disclosure;

FIG. 2A illustrates an enlarged view of the structure in the dotted-circle A as shown in FIG. 1A, according to some embodiments of the present disclosure;

FIG. 2B illustrates an enlarged view of the structure in the dotted-circle A as shown in FIG. 1A, according to some embodiments of the present disclosure;

FIG. 2C illustrates an enlarged view of the structure in the dotted-circle B as shown in FIG. 1B, according to some embodiments of the present disclosure;

FIG. 2D illustrates an enlarged view of the structure in the dotted-circle B as shown in FIG. 1B, according to some embodiments of the present disclosure;

FIG. 3 illustrates an Energy dispersive X-Ray (EDX) analysis, according to some embodiments of the present disclosure;

FIGS. 4A, 4B, 4C, and 4D illustrate operations for fabricating a semiconductor device, according to some embodiments of the present disclosure;

FIGS. 5A, 5B, 5C, 5D and 5E illustrate operations for fabricating a semiconductor device, according to some embodiments of the present disclosure;

FIGS. 6A, 6B, 6C, 6D and 6E illustrate operations for fabricating a semiconductor device, according to some comparative embodiments of the present disclosure;

FIG. 7 illustrates an enlarged view of the structure in the dotted-circle D as shown in FIG. 6E, according to some embodiments of the present disclosure;

FIG. 8 illustrates an Energy dispersive X-Ray (EDX) analysis, according to some comparative embodiments of the present disclosure.

### DETAILED DESCRIPTION

Embodiments of the present disclosure are discussed in detail below. It should be appreciated, however, that the present disclosure provides many applicable concepts that can be embodied in a wide variety of specific contexts. It should be appreciated that the following disclosure provides for many different embodiments, or examples, for implementing different features of the provided subject matter. Specific examples of components and arrangements are described below. These are, of course, merely examples and are not intended to be limiting.

The following embodiments or examples as illustrated in the drawings are described using a specific language. It should be appreciated, however, that the specific embodiments discussed are merely illustrative and do not limit the scope of the disclosure. In addition, it should be appreciated by persons having ordinary skill in the art that any changes and/or modifications of the disclosed embodiments as well as any further applications of the principles disclosed herein are encompassed within the scope of the present disclosure.

In addition, the present disclosure may repeat reference numerals and/or letters in the various examples. This repetition is for the purpose of simplicity and clarity and does not in itself dictate a relationship between the various embodiments and/or configurations discussed.

Gallium nitride (GaN) is anticipated to be the key material for a next generation power semiconductor device, having the properties of a higher breakdown strength, faster switching speed, higher thermal conductivity, lower on-resistance (Rₒₙ) and higher current gain. Power devices which include this wide-bandgap semiconductor material can significantly outperform the traditional Si-based power chips (for example, MOSFETs). Radio frequency (RF) devices which include this wide-bandgap semiconductor material can significantly outperform the traditional Si-based RF devices. As such, GaN-based power devices/RF devices will play a key role in the market of power conversion products and RF products, which includes battery chargers, smartphones, computers, servers, base stations, automotive electronics, lighting systems and photovoltaics.

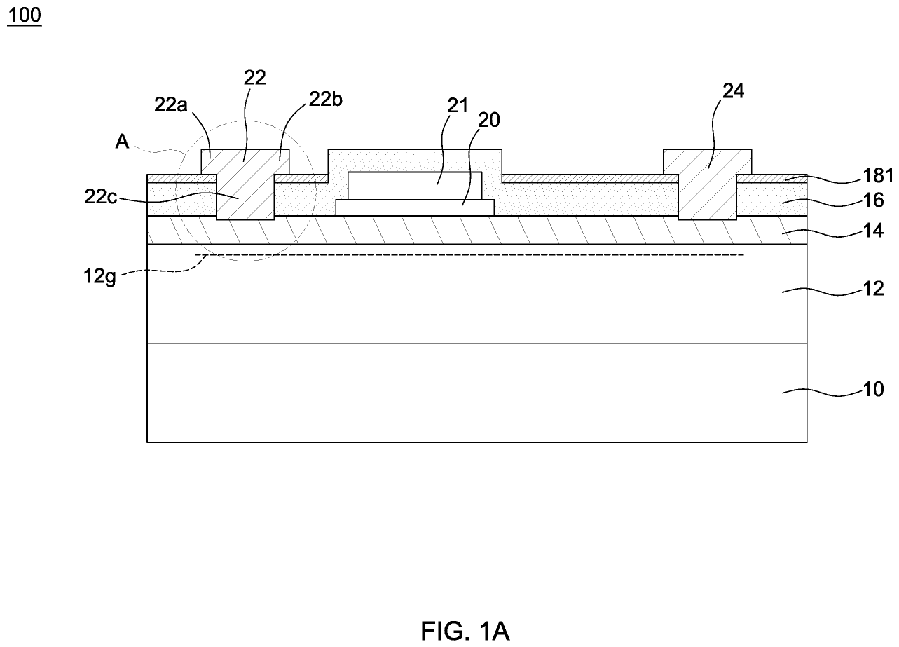

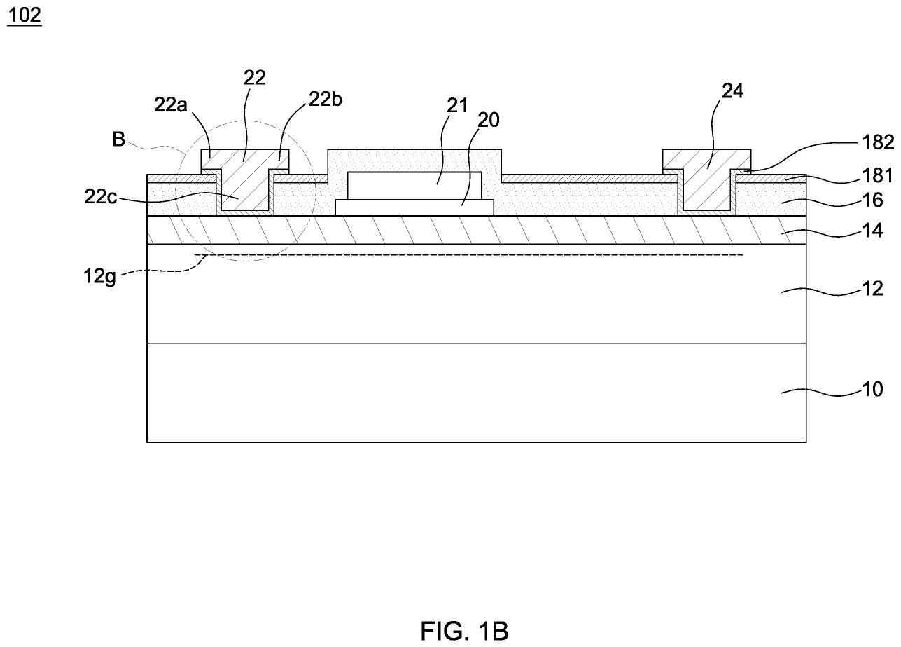

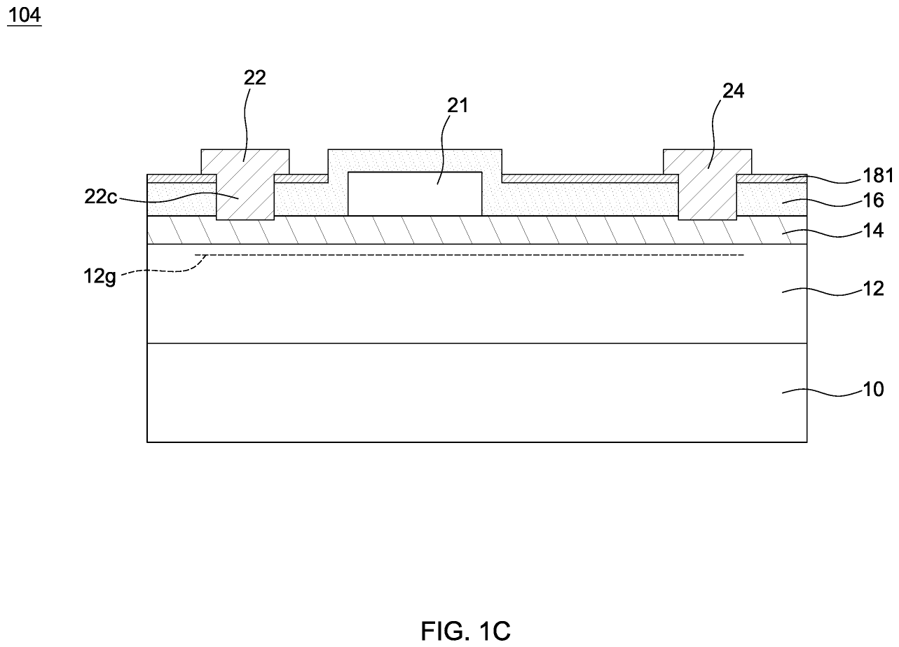

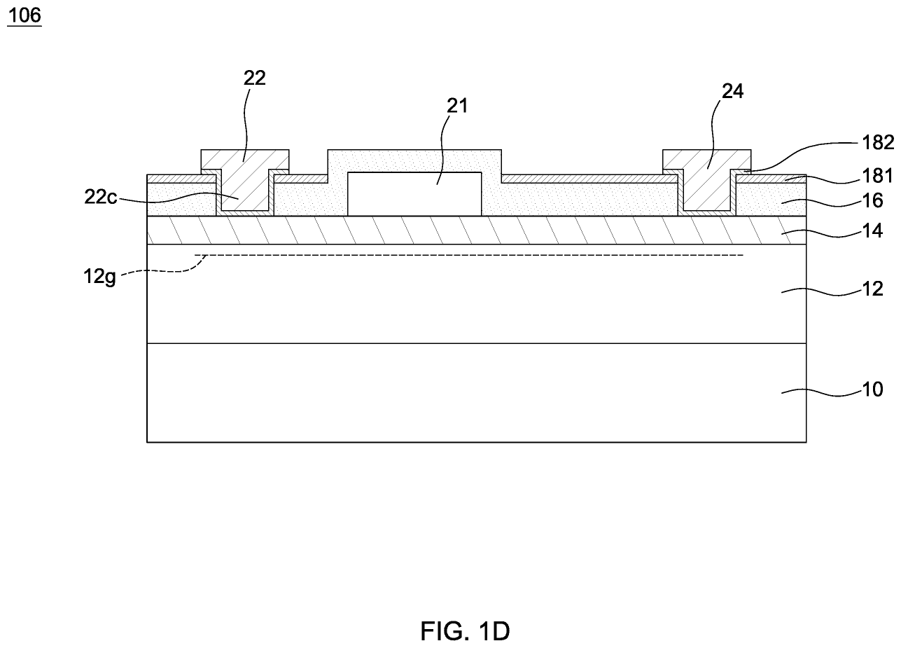

FIG. 1A illustrates a cross-sectional view of a semiconductor device according to some embodiments of the present disclosure.

FIG. 1A shows a semiconductor device 100. The semiconductor device 100 may include a substrate 10, a nitride semiconductor layer 12, a nitride semiconductor layer 14, a passivation layer 16 and an adhesive layer 181. The semiconductor device 100 further includes a semiconductor gate 20, and a gate conductor 21 disposed on the semiconductor gate 20. The semiconductor gate 20 and the gate conductor 21 may form the gate of the semiconductor device 100. Although not illustrated in FIG. 1A, the semiconductor device 100 may further include a conductive contact extending through the passivation layer 16 and in contact with the gate conductor 21.

The semiconductor device 100 further includes conductive contacts 22 and 24 in contact with the nitride semiconductor layer 14. An ohmic contact may be formed between conductive contact 22 and the nitride semiconductor layer 14. An ohmic contact may be formed between the conductive contact 24 and the nitride semiconductor layer 14. The conductive contacts 22 and 24 may form the source/drain electrodes of the semiconductor device 100.

The semiconductor device 100 can be an enhancement mode (E-mode) transistor. The semiconductor device 100 can be an enhancement mode high electron mobility transistor (HEMT).

The conductive contact 22 may include a portion 22a disposed on the adhesive layer 181, a portion 22b disposed on the adhesive layer 181, and a portion 22c extending through the adhesive layer 181 into the passivation layer 16. The portion 22a of the conductive contact 22 can also be referred to as an overhang in the subsequent paragraphs of the present disclosure. The portion 22b of the conductive contact 22 can also be referred to as an overhang in the subsequent paragraphs of the present disclosure.

The conductive contacts 22 and 24 can have a T-shaped profile. The portions 22a, 22b and 22c of the conductive contact 22 may form a “T” shape. In some other embodiments, the conductive contacts 22 and 24 may have a profile different from a “T” shape.

The portion 22a/22b can be a portion of the conductive contact 22 that is away from the nitride semiconductor layer 14, and the portion 22c can be a portion of the conductive contact 22 that is adjacent the nitride semiconduct or layer 14. The portion 22a/22b can be a portion of the conductive contact 22 that is away from the passivation layer 16, and the portion 22c can be a portion of the conductive contact 22 that is adjacent the passivation layer 16.

The substrate 10 may include, for example, but is not limited to, silicon (Si), doped Si, silicon carbide (SiC), germanium silicide (SiGe), gallium arsenide (GaAs), or other semiconductor materials. The substrate 10 may include, for example, but is not limited to, sapphire, silicon on insulator (SOI), or other suitable materials. The substrate 10 may include a silicon material. The substrate 10 may be a silicon substrate.

The nitride semiconductor layer 12 may be disposed on the substrate 10. The nitride semiconductor layer 12 may include group III-V materials. The nitride semiconductor layer 12 may include, for example, but is not limited to, group III nitride. The nitride semiconductor layer 12 may include a compound Al_{y}Ga_{(1-y)}N, in which y<1. The nitride semiconductor layer 12 may include GaN. The nitride semiconductor layer 12 can also be referred to as a channel layer.

The nitride semiconductor layer 14 may be disposed on the nitride semiconductor layer 12. The nitride semiconductor layer 14 may have a bandgap that is greater than that of the nitride semiconductor layer 12. A heterojunction may be formed between the nitride semiconductor layer 14 and the nitride semiconductor layer 12. The polarization of the heterojunction of different nitrides forms a two-dimensional electron gas (2DEG) region 12g in the nitride semiconductor layer 12. The 2DEG region 12g is usually formed in the layer that has a lower bandgap (e.g., GaN). The nitride semiconductor layer 14 can also be referred to as a barrier layer.

The nitride semiconductor layer 14 may include group III-V materials. The nitride semiconductor layer 14 may include, for example, but is not limited to, group III nitride. The nitride semiconductor layer 14 may include a compound Al_{y}Ga_{(1-y)}N, in which 0<y<1. The nitride semiconductor layer 14 may include a compound Al_{y}Ga_{(1-y)}N, in which 0.1<y<0.35. In some embodiments, a material of the nitride semiconductor layer 14 may include AlGaN. In some embodiments, a material of the nitride semiconductor layer 14 may include undoped AlGaN.

The conductive contacts 22 and 24 may include conductive materials, for example, but not limited to, titanium (Ti), aluminium (Al), nickel (Ni), gold (Au), palladium (Pd), or any combinations or alloys thereof. Although not depicted in FIG. 1A, the conductive contacts 22 and 24 may include semiconductor materials.

The conductive materials can be evenly distributed within the conductive contacts 22 and 24. The semiconductor materials can be evenly distributed within the conductive contacts 22 and 24. The concentration of the conductive materials within the conductive contacts 22 and 24 can be greater than that of the semiconductor materials within the conductive contacts 22 and 24.

The semiconductor materials can be evenly mixed with the conductive materials or alloys of the conductive contacts 22 and 24. The semiconductor materials and the conductive materials of the conductive contacts 22 and 24 can form compounds. In some embodiments, the semiconductor materials may include one or more of, for example, carbon (C), silicon (Si), germanium (Ge), tin (Sn), sulfur (S), selenium (Se), or tellurium (Te).

The semiconductor gate 20 may be disposed on the nitride semiconductor layer 14. The semiconductor gate 20 may be in contact with the nitride semiconductor layer 14. The semiconductor gate 20 may include a group III-V layer. The semiconductor gate 20 may include, for example, but is not limited to, group III nitride. The semiconductor gate 20 may include a compound Al_{y}Ga_{(1-y)}N, in which y<1. In some embodiments, a material of the semiconductor gate 20 may include a p-type doped group III-V layer. In some embodiments, a material of the semiconductor gate 20 may include p-type doped GaN.

The gate conductor 21 can be in contact with the semiconductor gate 20. The gate conductor 21 can be covered by the passivation layer 16. The gate conductor 21 can be surrounded by the passivation layer 16. The gate conductor 21 may include, for example, but is not limited to, titanium (Ti), tantalum (Ta), tungsten (W), aluminum (Al), cobalt (Co), copper (Cu), nickel (Ni), platinum (Pt), lead (Pb), molybdenum (Mo) and compounds thereof (such as, but not limited to, titanium nitride (TiN), tantalum nitride (TaN), other conductive nitrides, or conductive oxides)), metal alloys (such as aluminum-copper alloy (Al-Cu)), or other suitable materials.

The passivation layer 16 may include, for example, but is not limited to, oxides and/or nitrides, such as silicon nitride (SiN) and/or silicon oxide (SiO₂). The passivation layer 16 may include silicon nitride and/or silicon oxide formed by a non-plasma film formation process.

The adhesive layer 181 may include a nitride layer. The adhesive layer 181 may include a metal nitride layer. The adhesive layer 181 may include, for example, but is not limited to, TiN, AlN and the combination thereof.

The adhesive layer 181 may have a uniform thickness. The adhesive layer 181 may have a consistent thickness. The adhesive layer 181 may have a constant thickness. The adhesive layer 181 may include a thickness ranging from approximately 4.5 nm to approximately 15 nm. The adhesive layer 181 may include a thickness ranging from approximately 4.5 nm to approximately 9 nm. The adhesive layer 181 may include a thickness of about 5 nm.

FIG. 1B illustrates a cross-sectional view of a semiconductor device according to some embodiments of the present disclosure.

FIG. 1B shows a semiconductor device 102. The semiconductor device 102 may include a substrate 10, a nitride semiconductor layer 12, a nitride semiconductor layer 14, a passivation layer 16, an adhesive layer 181 and an intermediate layer 182. The semiconductor device 102 further includes a semiconductor gate 20, and a gate conductor 21 disposed on the semiconductor gate 20. The semiconductor gate 20 and the gate conductor 21 may form the gate of the semiconductor device 102.

The semiconductor device 102 further includes conductive contacts 22 and 24 in contact with the nitride semiconductor layer 14. The conductive contacts 22 and 24 may form the source/drain electrodes of the semiconductor device 102. The conductive contact 22 includes portions 22a, 22b and 22c. The semiconductor device 102 can be an E-mode transistor. The semiconductor device 102 can be an E-mode HEMT.

The semiconductor device 102 of FIG. 1B is similar to the semiconductor device 100 shown in FIG. 1A, except that the semiconductor device 102 further comprises an intermediate layer 182. The substrate 10, the nitride semiconductor layer 12, the nitride semiconductor layer 14, the passivation layer 16, the adhesive layer 181, the semiconductor gate 20, the gate conductor 21, and the conductive contacts 22 and 24 of the semiconductor device 102 may include materials and structures similar to those as described in accordance with the semiconductor device 100, and thus the details are not repeated here.

The intermediate layer 182 may be disposed near the bottom of the conductive contact 22/24. The intermediate layer 182 may be disposed between the conductive contact 22/24 and the passivation layer 16. The intermediate layer 182 may be disposed between the conductive contact 22/24 and the adhesive layer 181. The intermediate layer 182 can be deemed as a portion of the conductive contact 22/24.

The intermediate layer 182 may have a uniform thickness. The intermediate layer 182 may have a consistent thickness. The intermediate layer 182 may have a constant thickness. The intermediate layer 182 may include a thickness ranging from approximately 4.5 nm to approximately 15 nm. The intermediate layer 182 may include a thickness ranging from approximately 4.5 nm to approximately 9 nm. The intermediate layer 182 may include a thickness of about 5 nm.

The intermediate layer 182 may not affect the transmission of the carriers. The intermediate layer 182 may not degrade the transmission of the carriers. The intermediate layer 182 may not affect the transmission of the electrons. The intermediate layer 182 may not affect the transmission of the electrons between the nitride semiconductor layer 14 and the conductive contact 22. The intermediate layer 182 may not affect the transmission of the electrons between the nitride semiconductor layer 14 and the conductive contact 24.

The intermediate layer 182 may form an ohmic contact with the nitride semiconductor layer 14. The intermediate layer 182 may form a low-resistance ohmic contact. The intermediate layer 182 may reduce the resistance of an ohmic contact to about 0.3 Ω·mm.

The intermediate layer 182 and the conductive contact 22 may form an ohmic contact with the nitride semiconductor layer 14. The intermediate layer 182 may stop diffusion of the element of the conductive contact 22. The intermediate layer 182 may block diffusion of the element of the conductive contact 22. The intermediate layer 182 may alleviate diffusion of the element of the conductive contact 22. The intermediate layer 182 may prevent the element of the conductive contact 22 from entering the nitride semiconductor layer 14. The intermediate layer 182 may make the nitride semiconductor layer 14 devoid of the element of the conductive contact 22. The intermediate layer 182 may make the nitride semiconductor layer 14 devoid of at least one of titanium, aluminum, and silicon of the conductive contact 22.

The intermediate layer 182 and the conductive contact 24 may form an ohmic contact with the nitride semiconductor layer 14. The intermediate layer 182 may stop diffusion of the element of the conductive contact 24. The intermediate layer 182 may block diffusion of the element of the conductive contact 24. The intermediate layer 182 may alleviate diffusion of the element of the conductive contact 24. The intermediate layer 182 may prevent the element of the conductive contact 24 from entering the nitride semiconductor layer 14. The intermediate layer 182 may make the nitride semiconductor layer 14 devoid of the element of the conductive contact 24. The intermediate layer 182 may make the nitride semiconductor layer 14 devoid of at least one of titanium, aluminum, and silicon of the conductive contact 24.

The intermediate layer 182 may include a nitride layer. The intermediate layer 182 may include a metal nitride layer. The intermediate layer 182 may include, for example, but is not limited to, TiN, AlN and the combination thereof. In some embodiments, the intermediate layer 182 may include materials similar to or identical to those of the adhesive layer 181.

FIG. 1C illustrates a cross-sectional view of a semiconductor device according to some embodiments of the present disclosure.

FIG. 1C shows a semiconductor device 104. The semiconductor device 104 may include a substrate 10, a nitride semiconductor layer 12, a nitride semiconductor layer 14, a passivation layer 16 and an adhesive layer 181. The semiconductor device 104 further includes a gate conductor 21. The gate conductor 21 can be in direct contact with the nitride semiconductor layer 14. The gate conductor 21 may form the gate of the semiconductor device 104. Although not illustrated in FIG. 1C, the semiconductor device 104 may further include a conductive contact extending through the passivation layer 16 and in contact with the gate conductor 21.

The semiconductor device 104 further includes conductive contacts 22 and 24 in contact with the nitride semiconductor layer 14. An ohmic contact may be formed between conductive contact 22 and the nitride semiconductor layer 14. An ohmic contact may be formed between the conductive contact 24 and the nitride semiconductor layer 14. The conductive contacts 22 and 24 may form the source/drain electrodes of the semiconductor device 104.

The semiconductor device 104 can be a depletion mode (D-mode) transistor. The semiconductor device 104 can be a D-mode HEMT.

The semiconductor device 104 of FIG. 1C is similar to the semiconductor device 100 shown in FIG. 1A, except that the semiconductor gate 20 is absent from the semiconductor device 104.

The substrate 10, the nitride semiconductor layer 12, the nitride semiconductor layer 14, the passivation layer 16, the adhesive layer 181, the gate conductor 21, and the conductive contacts 22 and 24 of the semiconductor device 104 may include materials and structures similar to those as described in accordance with the semiconductor device 100, and thus the details are not repeated here.

FIG. 1D illustrates a cross-sectional view of a semiconductor device according to some embodiments of the present disclosure.

FIG. 1D shows a semiconductor device 106. The semiconductor device 106 may include a substrate 10, a nitride semiconductor layer 12, a nitride semiconductor layer 14, a passivation layer 16, an adhesive layer 181 and an intermediate layer 182. The semiconductor device 106 further includes a gate conductor 21. The gate conductor 21 can be in direct contact with the nitride semiconductor layer 14. The gate conductor 21 may form the gate of the semiconductor device 106. Although not illustrated in FIG. 1D, the semiconductor device 106 may further include a conductive contact extending through the passivation layer 16 and in contact with the gate conductor 21.

The semiconductor device 106 further includes conductive contacts 22 and 24 in contact with the nitride semiconductor layer 14. An ohmic contact may be formed between conductive contact 22 and the nitride semiconductor layer 14. An ohmic contact may be formed between the conductive contact 24 and the nitride semiconductor layer 14. The conductive contacts 22 and 24 may form the source/drain electrodes of the semiconductor device 106.

The semiconductor device 106 can be a depletion mode (D-mode) transistor. The semiconductor device 106 can be a D-mode HEMT.

The semiconductor device 106 of FIG. 1D is similar to the semiconductor device 102 shown in FIG. 1B, except that the semiconductor gate 20 is absent from the semiconductor device 106.

The substrate 10, the nitride semiconductor layer 12, the nitride semiconductor layer 14, the passivation layer 16, the adhesive layer 181, the intermediate layer 182, the gate conductor 21, and the conductive contacts 22 and 24 of the semiconductor device 104 may include materials and structures similar to those as described in accordance with the semiconductor device 102, and thus the details are not repeated here.

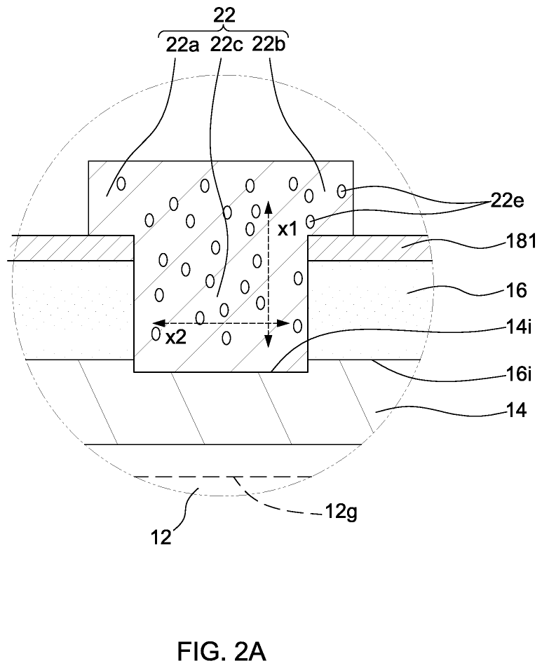

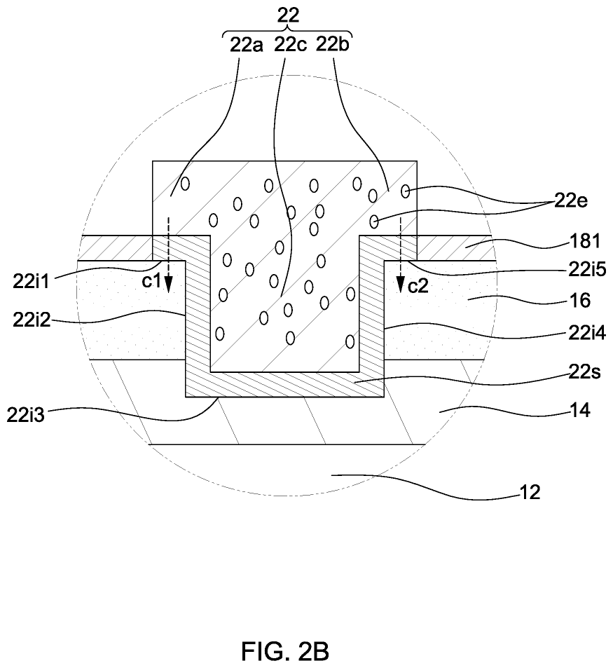

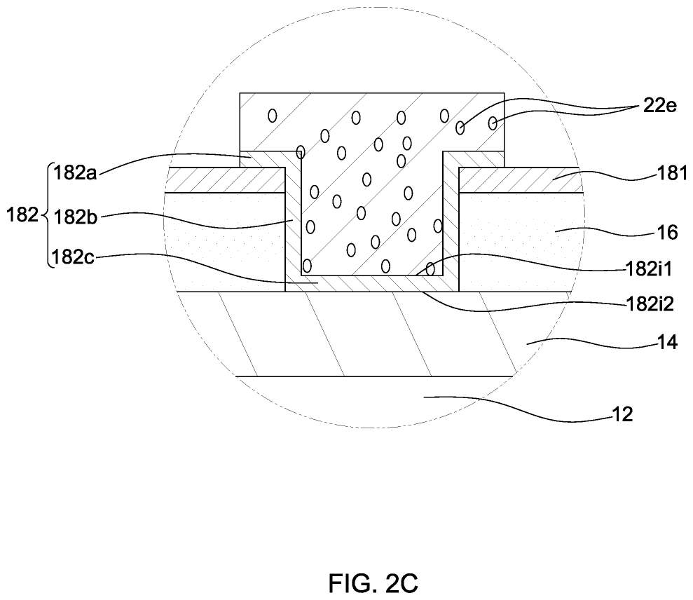

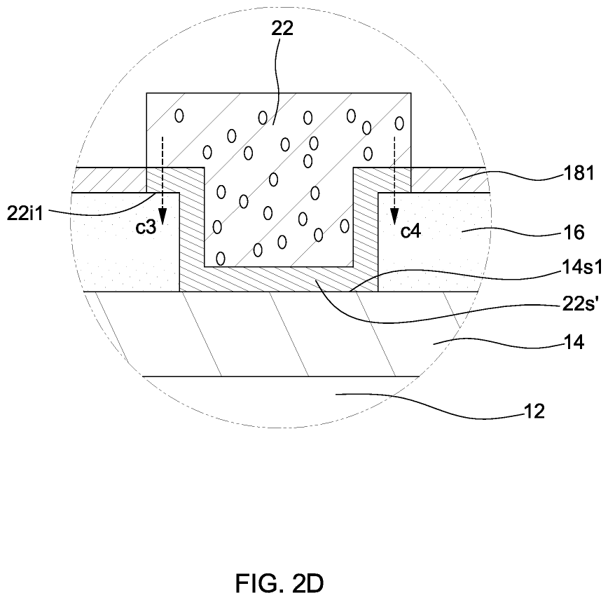

FIG. 2A illustrates an enlarged view of the structure in the dotted-circle A as shown in FIG. 1A, according to some embodiments of the present disclosure. The structure shown in FIG. 2A can be an enlarged view of the dotted-circle A of the semiconductor device 100 before an annealing process is performed.

The conductive contact 22 may include semiconductor material 22e. The semiconductor material 22e can be evenly distributed within the conductive contact 22. The semiconductor material 22e can be evenly mixed with the conductive materials or alloys of the conductive contact 22. The semiconductor material 22e and the conductive materials of the conductive contact 22 can form compounds. In some embodiments, the semiconductor material 22e may include one or more of, for example, carbon (C), silicon (Si), germanium (Ge), Tin (Sn), sulfur (S), Selenium (Se), or tellurium (Te).

The semiconductor material 22e can be evenly distributed within the portions 22a, 22b and 22c. A concentration of the semiconductor material 22e can be evenly distributed within the conductive contact 22 along a vertical axis x1. A concentration of the semiconductor material 22e can be evenly distributed within the conductive contact 22 along a horizontal axis x2.

The concentration mentioned in the present disclosure can be the mass concentration. The concentration mentioned in the present disclosure can be the volume concentration. The concentration mentioned in the present disclosure can be the Molar concentration. The concentration mentioned in the present disclosure can be the number concentration.

The concentration mentioned in the present disclosure can be the mass fraction (weight fraction). The concentration mentioned in the present disclosure can be the volume fraction. The concentration mentioned in the present disclosure can be the Molar fraction. The concentration mentioned in the present disclosure can be the number fraction.

A concentration of the semiconductor material 22e in the conductive contact 22 may range from approximately 0.1% to approximately 0.3%. A concentration of the semiconductor material 22e in the conductive contact 22 may range from approximately 0.3% to approximately 0.5%. A concentration of the semiconductor material 22e in the conductive contact 22 may range from approximately 0.5% to approximately 0.8%. A concentration of the semiconductor material 22e in the conductive contact 22 may range from approximately 0.2% to approximately 0.6%. A concentration of the semiconductor material 22e in the conductive contact 22 may range from approximately 0.2% to approximately 0.8%.

The portion 22c of the conductive contact 22 may extend into the nitride semiconductor layer 14. An interface 14i may exist between the portion 22c of the conductive contact 22 and the nitride semiconductor layer 14. An interface 16i may exist between the passivation layer 16 and the nitride semiconductor layer 14. The interface 14i can also be the bottom surface of the conductive contact 22.

The interface 14i may not be coplanar with the interface 16i. The interface 14i may be misaligned with the interface 16i. The interface 14i may be lower than the interface 16i. Referring to FIG. 2A, two-dimensional electron gas (2DEG) 12g can be formed within the nitride semiconductor layer 12. The interface 14i (i.e., the bottom surface of the conductive contact 22) being closer to the 2DEG 12g can improve the electrical connection of the conductive contact 22.

FIG. 2B illustrates an enlarged view of the structure in the dotted-circle A as shown in FIG. 1A, according to some embodiments of the present disclosure. The structure shown in FIG. 2B can be an enlarged view of the dotted-circle A of the semiconductor device 100 after an annealing process is performed.

The semiconductor material 22e and the conductive materials within the conductive contact 22 may form a salicide (self-aligned silicide) layer 22s during the annealing process. The salicide layer 22s can be conformally formed along the interfaces 22i1, 22i2, 22i4 and 22i5 between the conductive contact 22 and the passivation layer 16. The salicide layer 22s can be conformally formed along the interface 22i3 between the conductive contact 22 and the nitride semiconductor layer 14. In some embodiments, the salicide layer 22s can be deemed as a portion of the conductive contact 22.

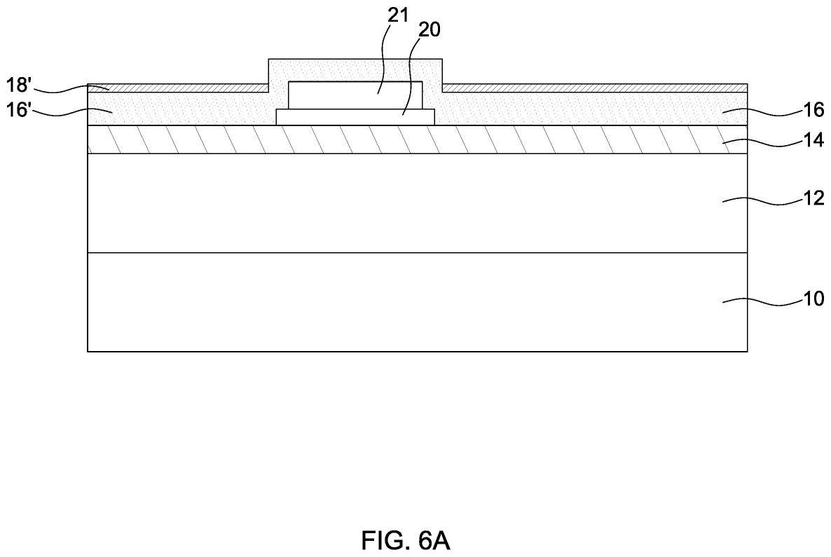

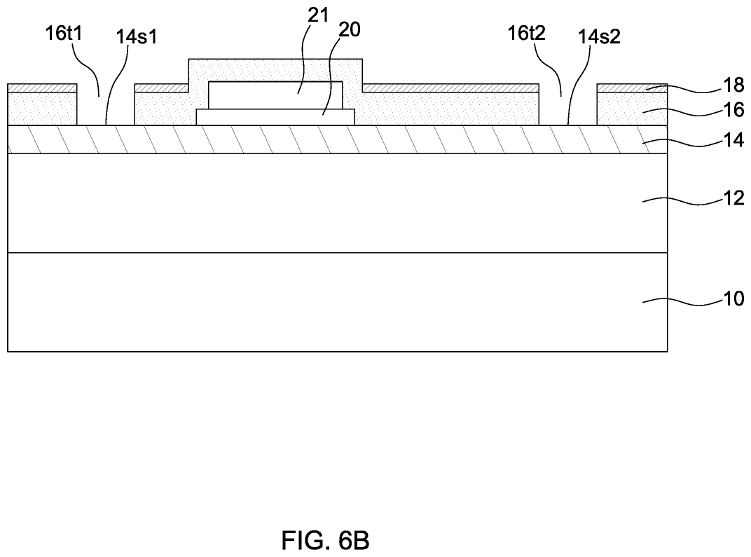

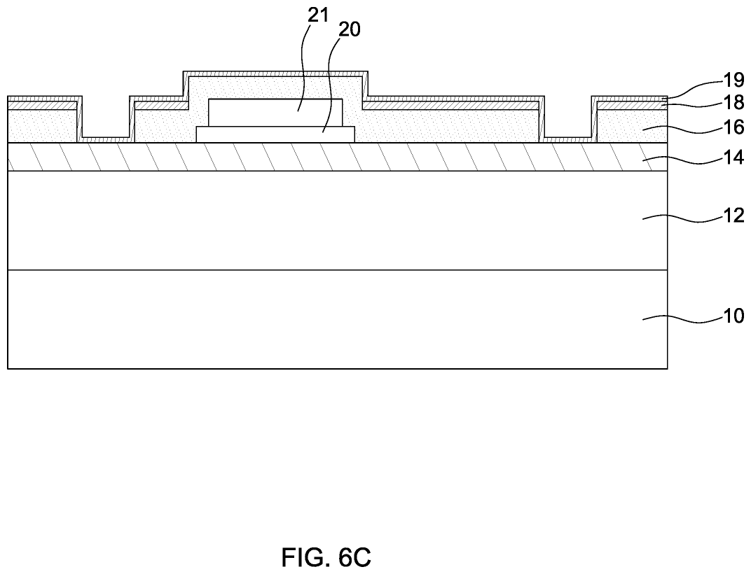

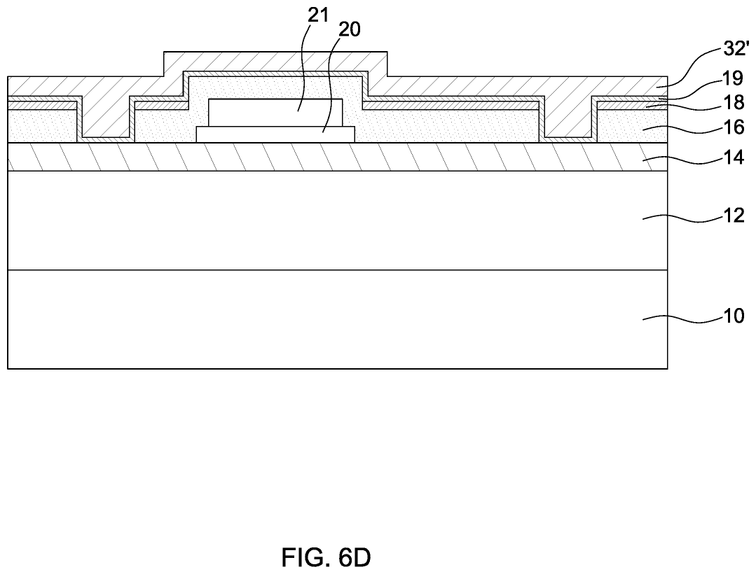

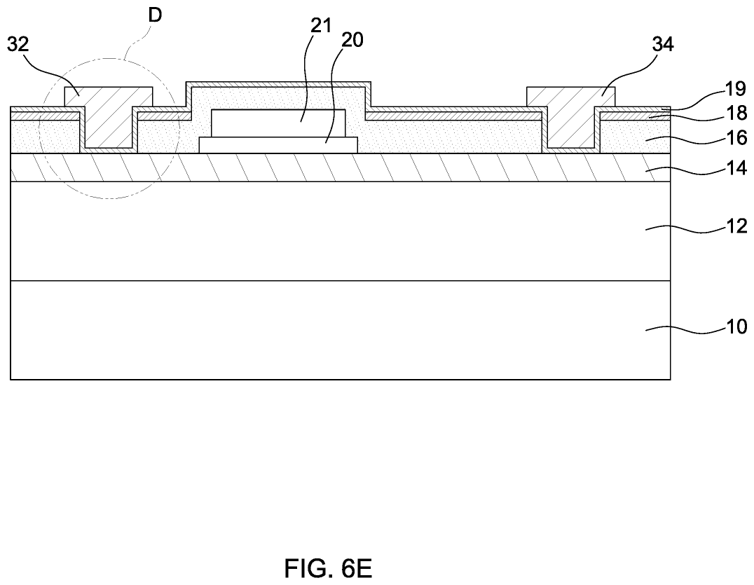

The salicide layer 22s may facilitate reducing the resistance of the ohmic contact formed between the conductive contact 22 and the nitride semiconductor layer 14. In some embodiments, the salicide layer 22s may facilitate reducing the resistance of the ohmic contact down to a level of 0.3 Ω mm. By incorporating semiconductor material 22e into the conductive contact 22, the salicide layer 22s can be formed, without disposing an additional silicon layer before the conductive contact 22 is formed. The manufacturing process, which includes disposing an additional silicon layer before a conductive contact is formed, will be described in accordance with FIGS. 6A-6E.

By incorporating semiconductor material 22e into the conductive contact 22, the step of disposing an additional silicon layer before the conductive contact 22 is formed can be eliminated. The elimination of the additional silicon layer may facilitate reducing the overall cost of manufacturing.

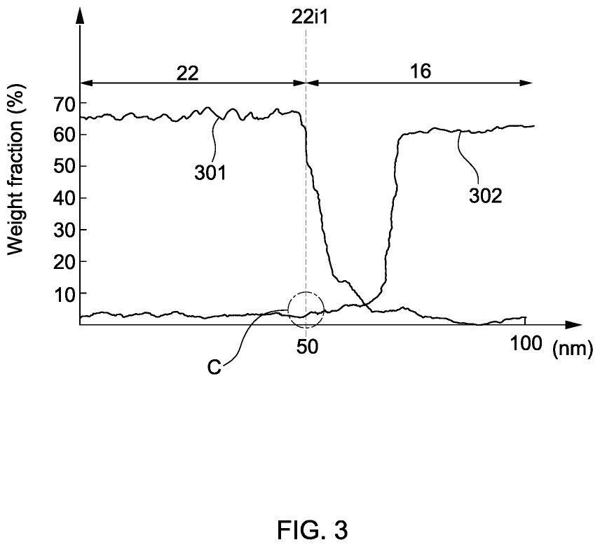

Energy dispersive X-Ray (EDX) analysis using a scanning electron microscope (SEM) can be performed along the dashed line c1 and c2 of FIG. 2B. The EDX analysis results may be helpful to understand the elemental composition or chemical characterization of the conductive contact 22. The EDX analysis results performed along the dashed line c1 and c2 will be illustrated in accordance with FIG. 3.

The salicide layer 22s includes the semiconductor material 22e. The concentration of the semiconductor material 22e within the salicide layer 22s can be greater than that within the conductive contact 22.

A concentration of the semiconductor material 22e in the salicide layer 22s may be greater than 0.8%. A concentration of the semiconductor material 22e in the salicide layer 22s may be greater than 1.2%. A concentration of the semiconductor material 22e in the salicide layer 22s may be greater than 1.8%. A concentration of the semiconductor material 22e in the salicide layer 22s may be greater than 2.5%.

A concentration of the semiconductor material 22e in the salicide layer 22s may be smaller than 6%. A concentration of the semiconductor material 22e in the salicide layer 22s may be smaller than 5%. A concentration of the semiconductor material 22e in the salicide layer 22s may be smaller than 4%. A concentration of the semiconductor material 22e in the salicide layer 22s may be smaller than 3%.

A concentration of the semiconductor material 22e in the salicide layer 22s may range from approximately 0.2% to approximately 3%. A concentration of the semiconductor material 22e in the salicide layer 22s may range from approximately 0.4% to approximately 3%. A concentration of the semiconductor material 22e in the salicide layer 22s may range from approximately 0.6% to approximately 4%. A concentration of the semiconductor material 22e in the salicide layer 22s may range from approximately 0.8% to approximately 5%. A concentration of the semiconductor material 22e in the salicide layer 22s may range from approximately 1% to approximately 6%.

FIG. 2C illustrates an enlarged view of the structure in the dotted-circle B as shown in FIG. 1B, according to some embodiments of the present disclosure. The structure shown in FIG. 2C can be an enlarged view of the dotted-circle B of the semiconductor device 102 before an annealing process is performed.

Referring to FIG. 2C, the intermediate layer 182 includes portions 182a, 182b and 182c. The portion 182a can be disposed on the adhesive layer 181. The portion 182b can be disposed between the conductive contact 22 and the passivation layer 16. The portion 182c can be disposed between the conductive contact 22 and the nitride semiconductor layer 14.

An interface 182i1 may be formed between the nitride semiconductor layer 14 and the passivation layer 16. An interface 182i2 may be formed between the intermediate layer 16 and the conductive contact 22.

The interface 182i1 may be substantially even. The interface 182i1 may be substantially flat. The interface 182i1 may be substantially smooth. The interface 182i1 may be substantially clear. The interface 182i1 may be substantially continuous.

The interface 182i2 may be substantially even. The interface 182i2 may be substantially flat. The interface 182i2 may be substantially smooth. The interface 182i2 may be substantially clear. The interface 182i2 may be substantially continuous.

The distance between the interface 182i1 and the interface 182i2 may range from approximately 4.5 nm to approximately 15 nm. The distance between the interface 182i1 and the interface 182i2 may range from approximately 4.5 nm to approximately 9 nm. The distance between the interface 182i1 and the interface 182i2 may be about 5 nm.

It should be noted that, the intermediate layer 182 may be applied due to the mechanism of the tunneling effect. It should be noted that, the intermediate layer 182 may be inserted between the nitride semiconductor layer 14 and the conductive contact 22 due to the mechanism of the tunneling effect.

The distance between the interface 182i1 and the interface 182i2 can be close enough to let carriers pass through. The distance between the interface 182i1 and the interface 182i2 can be close enough to let electrons pass through. The distance between the interface 182i1 and the interface 182i2 can be close enough to let holes pass through.

Due to the application of the intermediate layer 182, the nitride semiconductor layer 14 may be devoid of the element of the conductive contact 22. Due to the application of the intermediate layer 182, the element of the conductive contact 22 may not diffuse into the nitride semiconductor layer 14. Due to the application of the intermediate layer 182, the element (such as Ti) of the conductive contact 22 may not diffuse into the nitride semiconductor layer 14. Due to the application of the intermediate layer 182, the element (such as Si) of the conductive contact 22 may not diffuse into the nitride semiconductor layer 14. Due to the application of the intermediate layer 182, the resistance of the ohmic contact may be reduced. Due to the application of the intermediate layer 182, the resistance of the ohmic contact between the nitride semiconductor layer 14 and the conductive contact 22 may be reduced.

FIG. 2D illustrates an enlarged view of the structure in the dotted-circle B as shown in FIG. 1B, according to some embodiments of the present disclosure. The structure shown in FIG. 2D can be an enlarged view of the dotted-circle B of the semiconductor device 102 after an annealing process is performed.

The conductive materials of the conductive contact 22, the semiconductor material 22e within the conductive contact 22, a portion of the adhesive layer 181 (i.e., the portion of the adhesive layer 181 that is under the portion 182a of the intermediate layer 182), and the intermediate layer 182 may form a salicide (self-aligned silicide) layer 22s′ during the annealing process. In some embodiments, the salicide layer 22s′ can be deemed as a portion of the conductive contact 22.

EDX analysis using SEM can be performed along the dashed line c3 and c4 of FIG. 2D. The EDX analysis results may be helpful to understand the elemental composition or chemical characterization of the conductive contact 22. The EDX analysis results performed along the dashed line c3 and c4 will be illustrated in accordance with FIG. 3.

The salicide layer 22s′ includes the semiconductor material 22e. The concentration of the semiconductor material 22e within the salicide layer 22s′ can be greater than that within the conductive contact 22.

A concentration of the semiconductor material 22e in the salicide layer 22s′ may be greater than 0.8%. A concentration of the semiconductor material 22e in the salicide layer 22s′ may be greater than 1.2%. A concentration of the semiconductor material 22e in the salicide layer 22s′ may be greater than 1.8%. A concentration of the semiconductor material 22e in the salicide layer 22s′ may be greater than 2.5%.

A concentration of the semiconductor material 22e in the salicide layer 22s′ may be smaller than 6%. A concentration of the semiconductor material 22e in the salicide layer 22s′ may be smaller than 5%. A concentration of the semiconductor material 22e in the salicide layer 22s′ may be smaller than 4%. A concentration of the semiconductor material 22e in the salicide layer 22s′ may be smaller than 3%.

A concentration of the semiconductor material 22e in the salicide layer 22s′ may range from approximately 0.2% to approximately 3%. A concentration of the semiconductor material 22e in the salicide layer 22s′ may range from approximately 0.4% to approximately 3%. A concentration of the semiconductor material 22e in the salicide layer 22s′ may range from approximately 0.6% to approximately 4%. A concentration of the semiconductor material 22e in the salicide layer 22s′ may range from approximately 0.8% to approximately 5%. A concentration of the semiconductor material 22e in the salicide layer 22s′ may range from approximately 1% to approximately 6%.

FIG. 3 illustrates an Energy dispersive X-Ray (EDX) analysis, according to some embodiments of the present disclosure. FIG. 3 can be the EDX analysis results along the dashed line c1 or c2 of FIG. 2B. FIG. 3 can be the EDX analysis results along the dashed line c3 or c4 of FIG. 2D.

The vertical axis represents the weight fraction (%) of the elements. The horizontal axis represents the depth in the unit of nanometers (nm), along the arrow direction of the dashed lines c1-c4.

The curve 301 represents the weight fraction of the conductive material included in the conductive contact 22. In FIG. 3, the curve 301 represents the weight fraction of aluminium (Al). The curve 302 represents the weight fraction of the semiconductor material included in the conductive contact 22 and the passivation layer 16. In FIG. 3, the curve 302 represents the weight fraction of silicon (Si).

The weight fraction of the semiconductor material near the interface 22i1 (i.e., a contact between the conductive contact 22 and the passivation layer 16, see FIG. 2B) is devoid of a peak. The weight fraction of the semiconductor material near the interface 22i1 monotonically increases along a direction (the arrow direction of the dashed lines c1 and c2 of FIG. 2B; or the arrow direction of the dashed lines c3 and c4 of FIG. 2D) from the overhang (portion 22a or portion 22b) of the conductive contact 22 toward the passivation layer 16/nitride semiconductor layer 14.

The phrase “monotonically increases” in the present disclosure means that, along the direction from the overhang of the conductive contact 22 toward the passivation layer 16/nitride semiconductor layer 14, the concentration of the semiconductor material does not include a fall in value .

A concentration of the semiconductor material 22e near the interface 22i1 (see to the dotted circle C) may be smaller than 6%. A concentration of the semiconductor material 22e near the interface 22i1 may be smaller than 5%. A concentration of the semiconductor material 22e near the interface 22i1 may be smaller than 4%. A concentration of the semiconductor material 22e near the interface 22i1 may be smaller than 3%.

A concentration of the semiconductor material 22e near the interface 22i1 may range from approximately 0.2% to approximately 3%. A concentration of the semiconductor material 22e near the interface 22i1 may range from approximately 0.4% to approximately 3%. A concentration of the semiconductor material 22e near the interface 22i1 may range from approximately 0.6% to approximately 4%. A concentration of the semiconductor material 22e near the interface 22i1 may range from approximately 0.8% to approximately 5%. A concentration of the semiconductor material 22e near the interface 22i1 may range from approximately 1% to approximately 6%.

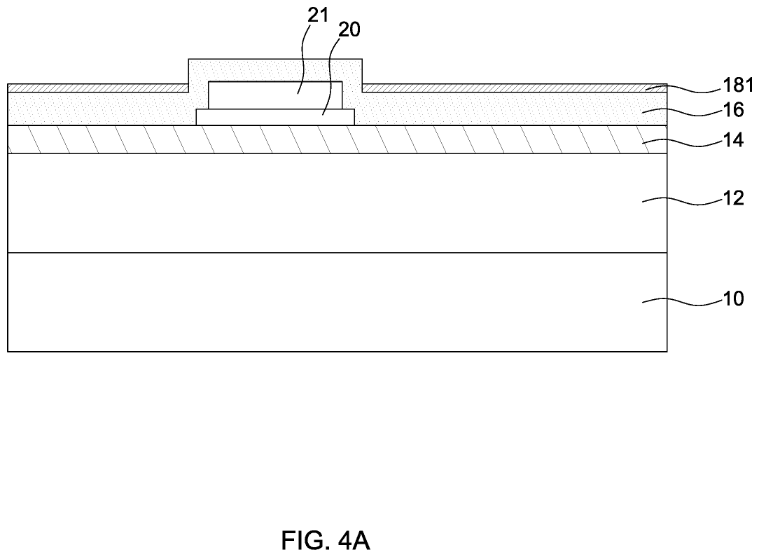

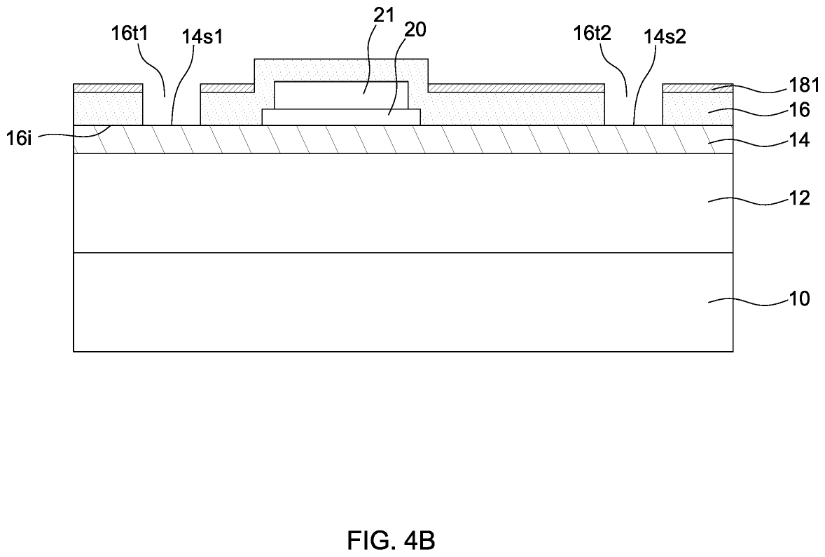

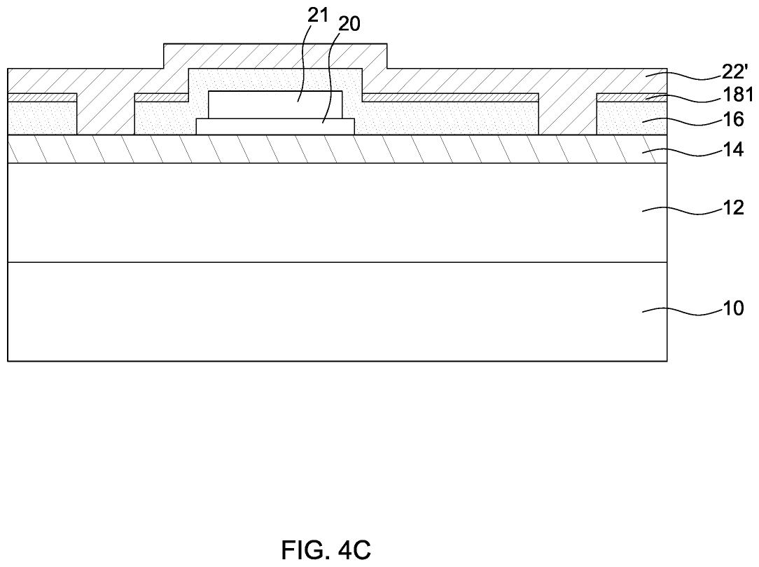

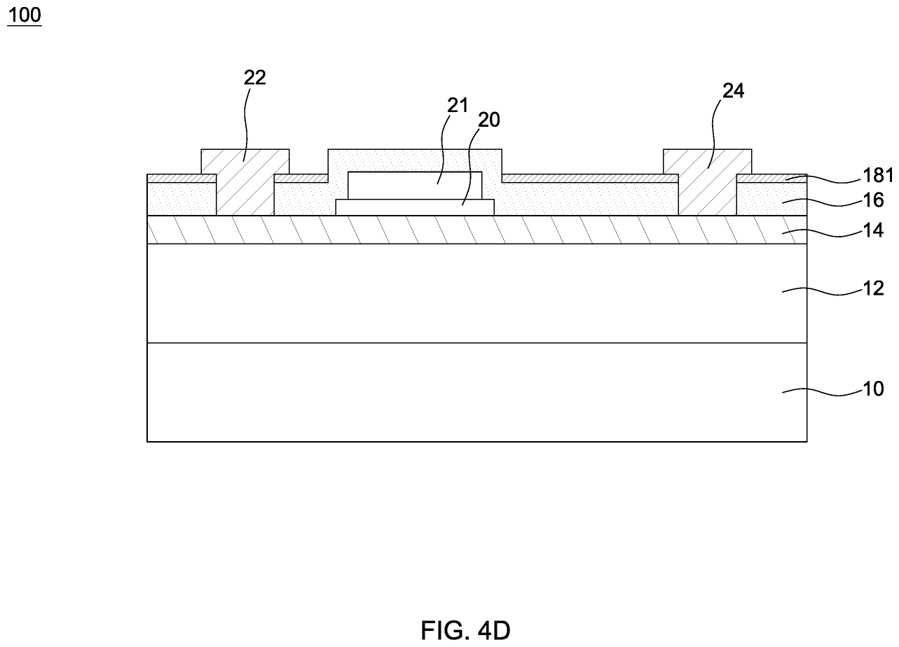

FIGS. 4A, 4B, 4C, and 4D illustrate operations for fabricating a semiconductor device, according to some embodiments of the present disclosure. The operations shown in FIGS. 4A, 4B, 4C, and 4D can be performed to produce the semiconductor 100 shown in FIG. 1A.

Referring to FIG. 4A, a semiconductor structure including a substrate 10, a nitride semiconductor layer 12, a nitride semiconductor layer 14, a passivation layer 16 and an adhesive layer 181, is provided. The semiconductor structure further includes a semiconductor gate 20 and a gate conductor 21 disposed on the semiconductor gate 20.

The substrate 10, the nitride semiconductor layer 12, the nitride semiconductor layer 14, the passivation layer 16, the adhesive layer 181, the semiconductor gate 20 and the gate conductor 21 may include materials/structures similar to or identical to those as described in accordance with FIG. 1A, and thus the details are not repeated here.

Referring to FIG. 4B, a trench/opening 16t1 is formed to expose a portion of the nitride semiconductor layer 14. The trench/opening 16t1 is formed to expose a surface 14s1 of the nitride semiconductor layer 14. In addition, a trench/opening 16t2 is formed to expose another portion of the nitride semiconductor layer 14. The trench/opening 16t2 is formed to expose a surface 14s2 of the nitride semiconductor layer 14.

In some embodiments, the surface 14s1 can be non-coplanar with the interface 16i between the passivation layer 16 and the nitride semiconductor layer 14. In some embodiments, the surface 14s1 can be lower than the interface 16i. In some embodiments, the surface 14s2 can be non-coplanar with the interface 16i between the passivation layer 16 and the nitride semiconductor layer 14. In some embodiments, the surface 14s2 can be lower than the interface 16i.

Referring to FIG. 4C, a conductive layer 22′ is formed to fill the trench/opening 16t1 and the trench/opening 16t2. The conductive layer 22′ can be conformally formed on the adhesive layer 181, within the trench/opening 16t1, on the passivation layer 16, and within the trench/opening 16t2. The conductive layer 22′ may include materials similar to or identical to those of the conductive contact 22 as described in accordance with FIG. 1A, and thus the details are not repeated here.

Referring to FIG. 4D, portions of the conductive layer 22′ can be removed so as to form the conductive contacts 22 and 24. For example, portions of the conductive layer 22′ are removed to expose the passivation layer 16 and the adhesive layer 181. After the conductive contacts 22 and 24 are formed, an annealing process can be performed. Although not shown in FIG. 4D, after the annealing process, a salicide layer (see FIG. 2B) can be formed between the conductive contact 22 and the passivation layer 16, and between the conductive contact 22 and the nitride semiconductor layer 14. In addition, after the annealing process, a salicide layer (see FIG. 2B) can be formed between the conductive contact 24 and the passivation layer 16, and between the conductive contact 24 and the nitride semiconductor layer 14.

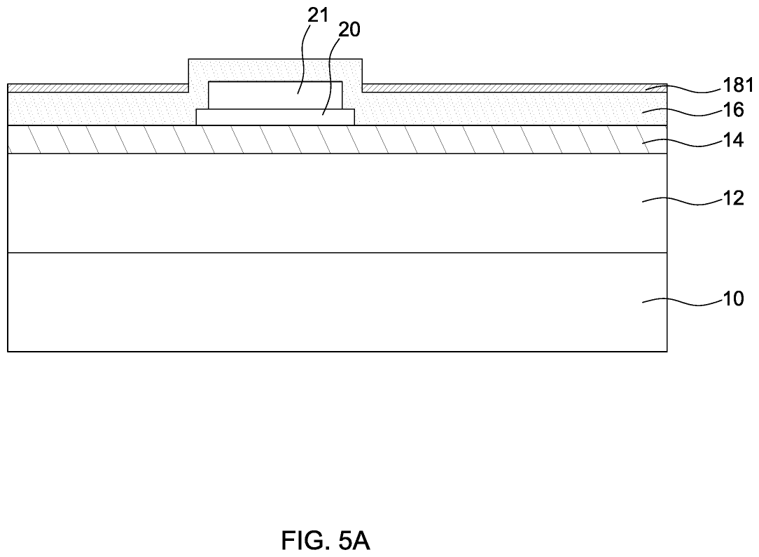

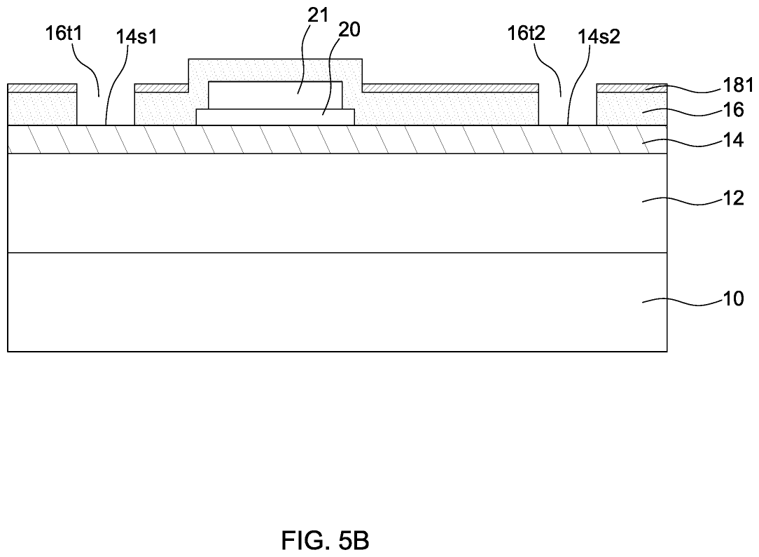

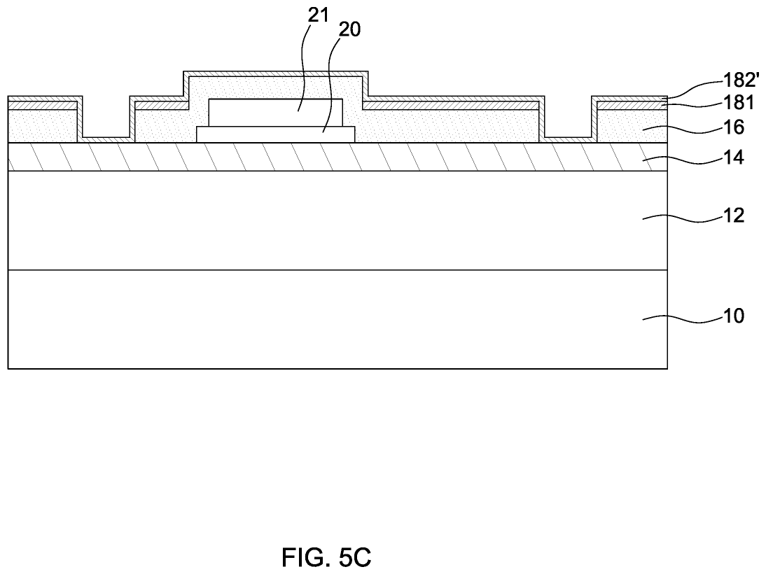

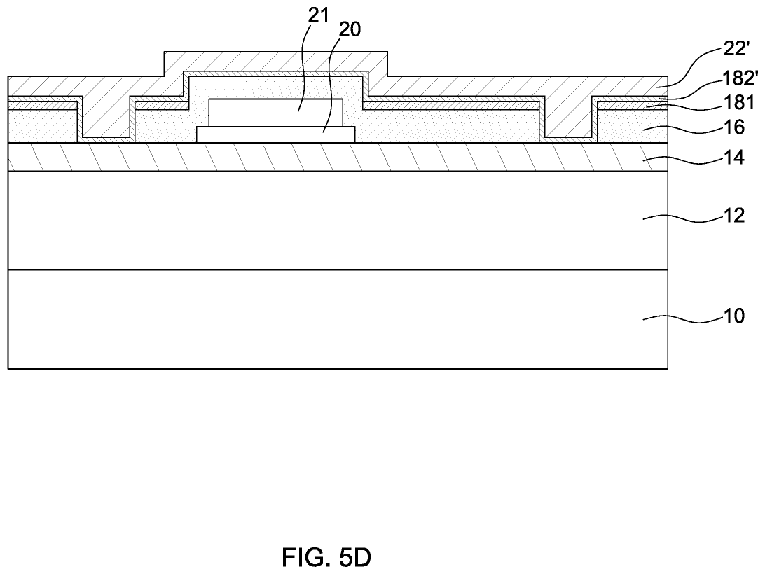

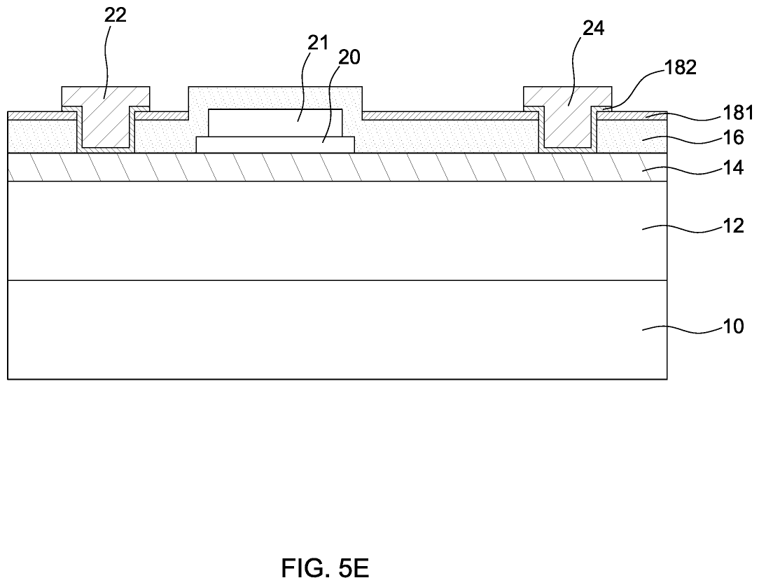

FIGS. 5A, 5B, 5C, 5D and 5E illustrate operations for fabricating a semiconductor device, according to some embodiments of the present disclosure. The operations shown in FIGS. 5A, 5B, 5C, 5D and 5E can be performed to produce the semiconductor 102 shown in FIG. 1B.

Referring to FIG. 5A, a semiconductor structure including a substrate 10, a nitride semiconductor layer 12, a nitride semiconductor layer 14, a passivation layer 16 and an adhesive layer 181, is provided. The semiconductor structure further includes a semiconductor gate 20 and a gate conductor 21 disposed on the semiconductor gate 20.

The substrate 10, the nitride semiconductor layer 12, the nitride semiconductor layer 14, the passivation layer 16, the adhesive layer 181, the semiconductor gate 20 and the gate conductor 21 may include materials/structures similar to or identical to those as described in accordance with FIG. 1A, and thus the details are not repeated here.

Referring to FIG. 5B, a trench/opening 16t1 is formed to expose a portion of the nitride semiconductor layer 14. The trench/opening 16t1 is formed to expose a surface 14s1 of the nitride semiconductor layer 14. In addition, a trench/opening 16t2 is formed to expose another portion of the nitride semiconductor layer 14. The trench/opening 16t2 is formed to expose a surface 14s2 of the nitride semiconductor layer 14.

Referring to FIG. 5C, an intermediate layer 182′ is formed. The intermediate layer 182′ can be conformally formed on the adhesive layer 181, along the sidewalls of the trench/opening 16t1, on the passivation layer 16, and along the sidewalls of the trench/opening 16t2. The intermediate layer 182′ may include materials similar to or identical to those of the intermediate layer 182 as described in accordance with FIG. 1B, and thus the details are not repeated here.

Referring to FIG. 5D, a conductive layer 22′ is formed to fill the trench/opening 16t1 and the trench/opening 16t2. The conductive layer 22′ can be conformally formed on the intermediate layer 182′ and within the trench/opening 16t1 and the trench/opening 16t2. The conductive layer 22′ may include materials similar to or identical to those of the conductive contact 22 as described in accordance with FIG. 1A, and thus the details are not repeated here.

Referring to FIG. 5E, portions of the conductive layer 22′ and portions of the intermediate layer 182′ can be removed so as to form the conductive contacts 22 and 24.

For example, portions of the conductive layer 22′ and the intermediate layer 182′ are removed to expose the passivation layer 16 and the adhesive layer 181. After the conductive contacts 22 and 24 are formed, an annealing process can be performed. Although not shown in FIG. 5E, after the annealing process, a salicide layer (see FIG. 2D) can be formed between the conductive contact 22 and the passivation layer 16, and between the conductive contact 22 and the nitride semiconductor layer 14. In addition, after the annealing process, a salicide layer (see FIG. 2D) can be formed between the conductive contact 24 and the passivation layer 16, and between the conductive contact 24 and the nitride semiconductor layer 14.

FIGS. 6A, 6B, 6C, 6D and 6E illustrate operations for fabricating a semiconductor device, according to some comparative embodiments of the present disclosure.

Referring to FIG. 6A, a semiconductor structure including a substrate 10, a nitride semiconductor layer 12, a nitride semiconductor layer 14, a passivation layer 16 and an adhesive layer 18′, is provided. The semiconductor structure further includes a semiconductor gate 20 and a gate conductor 21 disposed on the semiconductor gate 20.

The substrate 10, the nitride semiconductor layer 12, the nitride semiconductor layer 14, the passivation layer 16, the semiconductor gate 20 and the gate conductor 21 may include materials/structures similar to or identical to those as described in accordance with FIG. 1A, and thus the details are not repeated here. The adhesive layer 18′ may include materials similar to or identical to those of the adhesive layer 181 as described in accordance with FIG. 1A.

Referring to FIG. 6B, a trench/opening 16t1 is formed to expose a portion of the nitride semiconductor layer 14. The trench/opening 16t1 is formed to expose a surface 14s1 of the nitride semiconductor layer 14. In addition, a trench/opening 16t2 is formed to expose another portion of the nitride semiconductor layer 14. The trench/opening 16t2 is formed to expose a surface 14s2 of the nitride semiconductor layer 14. Furthermore, a portion of the adhesive layer 18′ (i.e., the portion of the adhesive layer 18′ that is above the gate conductor 21) is removed to expose a portion of the passivation layer 16, and then an adhesive layer 18 is formed.

Referring to FIG. 6C, a silicon layer 19 is formed. The silicon layer 19 can be conformally formed on the adhesive layer 18, along the sidewalls of the trench/opening 16t1, on the exposed portion of the passivation layer 16, and along the sidewalls of the trench/opening 16t2. In some embodiments, the silicon layer 19 may include nitride. In some embodiments, the silicon layer 19 may include silicon nitride (SiN).

Referring to FIG. 6D, a conductive layer 32′ is formed to fill the trench/opening 16t1 and the trench/opening 16t2. The conductive layer 32′ can be conformally formed on the silicon layer 19. The conductive layer 32′ can fill within the trench/opening 16t1 and the trench/opening 16t2. The conductive layer 32′ may include materials similar to or identical to those of the conductive contact 22 as described in accordance with FIG. 1A.

Referring to FIG. 6E, portions of the conductive layer 32′ can be removed so as to form the conductive contacts 32 and 34.

After the conductive contacts 32 and 34 are formed, an annealing process can be performed. Although not shown in FIG. 6E, after the annealing process, a salicide layer can be formed between the conductive contact 32 and the passivation layer 16, and between the conductive contact 32 and the nitride semiconductor layer 14. In addition, after the annealing process, a salicide layer can be formed between the conductive contact 34 and the passivation layer 16, and between the conductive contact 34 and the nitride semiconductor layer 14.

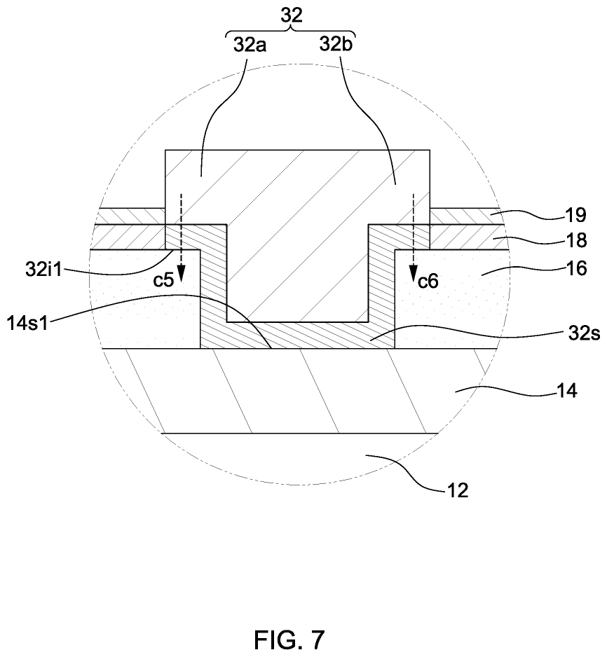

FIG. 7 illustrates an enlarged view of the structure in the dotted-circle D as shown in FIG. 6E, according to some embodiments of the present disclosure. The structure shown in FIG. 7 can be an enlarged view of the dotted-circle D of FIG. 6E after an annealing process is performed.

The conductive materials of the conductive contact 32, a portion of the silicon layer 19 (i.e., the portion of the silicon layer 19 that is under the portion 32a or 32b of the conductive contact 32), and a portion of the adhesive layer 18 (i.e., the portion of the adhesive layer 18 that is under the portion 32a or 32b of the conductive contact 32) may form a salicide (self-aligned silicide) layer 32s during the annealing process. In some embodiments, the salicide layer 32s can be deemed as a portion of the conductive contact 32.

By disposing the silicon layer 19 before disposing the conductive contacts 32 and 34, the salicide layer 32s can be formed. The salicide layer 32s may facilitate reducing the resistance of the ohmic contact formed between the conductive contact 32 and the nitride semiconductor layer 14. In some embodiments, the salicide layer 32s may facilitate reducing the resistance of the ohmic contact down to a level of 0.5 Ω·mm.

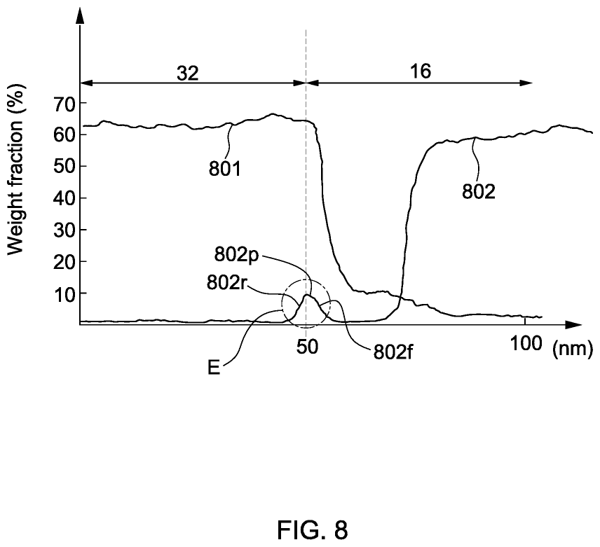

EDX analysis using SEM can be performed along the dashed line c5 and c6 of FIG. 7. The EDX analysis results may be helpful to understand the elemental composition or chemical characterization of the conductive contact 32. The EDX analysis results performed along the dashed line c5 and c6 will be illustrated in accordance with FIG. 8.

FIG. 8 illustrates an Energy dispersive X-Ray (EDX) analysis, according to some comparative embodiments of the present disclosure. FIG. 8 can be the EDX analysis results along the dashed line c5 or c6 of FIG. 7.

The vertical axis represents the weight fraction (%) of the elements. The horizontal axis represents the depth in the unit of nanometers (nm), along the arrow direction of the dashed lines c5 or c6 of FIG. 7.

The curve 801 represents the weight fraction of the conductive material included in the conductive contact 32. In FIG. 8, the curve 801 represents the weight fraction of aluminium (Al). The curve 802 represents the weight fraction of the semiconductor material included in the conductive contact 32 and the passivation layer 16. In FIG. 8, the curve 802 represents the weight fraction of silicon (Si).

Referring to the curve 802, the weight fraction of the semiconductor material near the interface 32i1 (i.e., an interface between the conductive contact 32 and the passivation layer 16, see FIG. 7) includes a peak (see the dotted circle E).

The “peak” in the present disclosure means that the concentration of the semiconductor material includes a fall following a rise. For example, as shown in the dotted circle E of FIG. 8, the curve 802 includes a peak 802p near the interface 32i1. The peak 802p can be defined by a rise 802r and a fall 802f following the rise 802r.

A concentration of the semiconductor material at the peak 802p can be greater than 3%. A concentration of the semiconductor material at the peak 802p can be greater than 3.5%. A concentration of the semiconductor material at the peak 802p can be greater than 4%. A concentration of the semiconductor material at the peak 802p can be greater than 4.5%. A concentration of the semiconductor material at the peak 802p can be greater than 5%. A concentration of the semiconductor material at the peak 802p can be greater than 5.5%. A concentration of the semiconductor material at the peak 802p can be greater than 6%.

As used herein, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially,” “substantial” and “about” are used to describe and account for small variations. When used in conjunction with an event or circumstance, the terms can refer to instances in which the event of circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

What is claimed is:

1. A semiconductor device, comprising:
a substrate;
a first nitride semiconductor layer disposed on the substrate;
a second nitride semiconductor layer disposed on the first nitride semiconductor layer and having a bandgap greater than that of the first nitride semiconductor layer, so as to form a heterojunction therebetween with a two-dimensional electron gas region;
a passivation layer disposed on the second nitride semiconductor layer;
a first adhesive layer disposed on the passivation layer; and
a conductive contact disposed on the first adhesive layer and extending through the first adhesive layer into the passivation layer, the conductive contact having a first overhang on the passivation layer and in direct contact with the first adhesive layer, and the conductive contact comprising a first element,
wherein a concentration of the first element is less than approximate 3% around to a contact between the first overhang and the passivation layer.

2. The semiconductor device according to claim 1, wherein the concentration of the first element is devoid of a peak between the first overhang and the passivation layer.

3. The semiconductor device according to claim 1, wherein the conductive contact comprising an intermediate layer having a first portion in contact with the second nitride semiconductor layer.

4. The semiconductor device according to claim 3, wherein the intermediate layer further including a second portion disposed above the first adhesive layer.

5. The semiconductor device according to claim 4, wherein the conductive contact further comprising a second overhang on the first adhesive layer, and a concentration of the first element is devoid of a peak between the second overhang and the passivation layer.

6. The semiconductor device according to claim 1, wherein the conductive contact includes the first element, and the first element is distributed substantially even within the conductive contact.

7. The semiconductor device according to claim 6, wherein the conductive contact includes a second element different from the first element, and the second element is distributed substantially even within the conductive contact.

8. The semiconductor device according to claim 1, wherein the conductive contact includes a portion extending into the second nitride semiconductor layer.

9. The semiconductor device according to claim 1, wherein a first interface between the conductive contact and the second nitride semiconductor layer is not coplanar with a second interface between the second nitride semiconductor layer and the passivation layer.

10. The semiconductor device according to claim 6, wherein a concentration of the first element of the conductive contact ranges from approximately 0.2% to approximately 0.6%.

11. A semiconductor device, comprising:
a substrate;
a first nitride semiconductor layer disposed on the substrate;
a second nitride semiconductor layer disposed on the first nitride semiconductor layer and having a bandgap greater than that of the first nitride semiconductor layer, so as to form a heterojunction therebetween with a two-dimensional electron gas region;
a passivation layer on the first nitride semiconductor layer;
a first adhesive layer disposed on the passivation layer;
a conductive contact having a first portion away from the second nitride semiconductor layer and a second portion adjacent the second nitride semiconductor layer, and the first portion of the conductive contact comprising a first semiconductor material.

12. The semiconductor device according to claim 11, wherein a concentration of the first semiconductor material in the first portion of the electrode ranges from approximately 0.2% to approximately 0.6%, a concentration of the first semiconductor material in the second portion of the electrode ranges from approximately 0.2% to approximately 0.6%, and a concentration of the first semiconductor material in the third portion of the electrode ranges from approximately 0.2% to approximately 0.6%.

13. The semiconductor device according to claim 11, wherein the concentration of the first semiconductor material is less than approximate 3% between the first portion of the conductive contact and the passivation layer.

14. The semiconductor device according to claim 11, wherein the conductive contact comprising an intermediate layer in contact with the first adhesive layer, the passivation layer and the second nitride semiconductor layer.

15. The semiconductor device according to claim 11, wherein the concentration of the first semiconductor material monotonically increases along a direction from the second portion of the conductive contact toward the second nitride semiconductor layer.

16. The semiconductor device according to claim 11, wherein the conductive contact includes a second element, and a concentration of the second material is greater than a concentration of the first semiconductor material.

17. The semiconductor device according to claim 16, wherein the first semiconductor material is silicon and the second element is aluminum.

18. A method for fabricating a semiconductor device, comprising:
providing a semiconductor structure having a substrate, a first nitride semiconductor layer and a passivation layer;
removing a portion of the passivation layer to form a trench exposing a surface of the first nitride semiconductor layer;
applying a conductive layer on the passivation layer to fill the trench, wherein the conductive layer includes a semiconductor material and a metal material.

19. The method according to claim 18, wherein the semiconductor material is distributed substantially even within the conductive layer.

20. The method according to claim 18, wherein a concentration of the semiconductor material ranges from approximately 0.2% to approximately 0.6%.
